(19) United States
(12) Patent Application Publication
(10) Pub. No.: US 2026/0047116 A1
(43) Pub. Date: Feb. 12, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Tatsuya ARAI, Nonoichi Ishikawa (JP); Hideaki NINOMIYA, Tatsuno Hyogo (JP); Toshiaki KOBAYASHI, Kanazawa Ishikawa (JP); Masato HAYASHI, Komatsu Ishikawa (JP)

(21) Appl. No.: 19/044,369

(22) Filed: Feb. 3, 2025

(30) Foreign Application Priority Data
Aug. 9, 2024 (JP) 2024-134405
Dec. 4, 2024 (JP) 2024-211697

(51) Int. Cl. H10D 12/00; H10D 62/10; H10D 89/60

(52) U.S. Cl. CPC H10D 12/481; H10D 12/415; H10D 62/106; H10D 89/601

(57) ABSTRACT

According to one embodiment, a semiconductor device includes first to fourth electrodes, a main element region, a fifth semiconductor region, a sense element region, an eighth semiconductor region, and a ninth semiconductor region. The main element region includes a first semiconductor region, a second semiconductor region, a third semiconductor region, a fourth semiconductor region, and a first gate electrode. The sense element region includes the first semiconductor region, the second semiconductor region, a sixth semiconductor region, a seventh semiconductor region, and a second gate electrode. An area of the sense element region in the first plane is smaller than an area of the main element region in the first plane. The eighth semiconductor region is provided around the sense element region. The ninth semiconductor region is provided between the main element region and the sense element region, and electrically connected to the eighth semiconductor region.

### CROSS-REFERENCE TO RELATED APPLICATIONS

This application is based upon and claims the benefit of priority from Japanese Patent Application No. 2024-134405, filed on Aug. 9, 2024 and Japanese Patent Application No.2024-211697, filed on Dec. 4, 2024; the entire contents of which are incorporated herein by reference.

### FIELD

Embodiments of the present invention generally relate to a semiconductor device.

### BACKGROUND

A semiconductor device may include a sense element for detecting a current in addition to a main element through which the current mainly flows. For this semiconductor device, there is a need for a technology that can suppress the occurrence of breakdown in the sense element.

### BRIEF DESCRIPTION OF THE DRAWINGS

FIG. 1 is a plan view illustrating a semiconductor device according to a first embodiment;

FIG. 2 is a II-II cross-sectional view of FIG. 1;

FIG. 3 is a cross-sectional view illustrating a semiconductor device according to a second embodiment;

FIG. 4 is a cross-sectional view illustrating a semiconductor device according to a third embodiment;

FIG. 5 is a cross-sectional view illustrating a semiconductor device according to a fourth embodiment;

FIG. 6 is a cross-sectional view illustrating an example of a VI-VI cross-section of FIG. 5;

FIGS. 7A and 7B are cross-sectional views illustrating other examples of the VI-VI cross-section;

FIG. 8 is a cross-sectional view illustrating a semiconductor device according to a fifth embodiment;

FIGS. 9A to 9C are enlarged cross-sectional views of portions of FIG. 8.

### DETAILED DESCRIPTION

According to one embodiment, a semiconductor device includes a first electrode, a main element region, a fifth semiconductor region, a sense element region, an eighth semiconductor region, a ninth semiconductor region, a second electrode, a third electrode, and a fourth electrode. The main element region includes a first semiconductor region of a first conductivity type, a second semiconductor region of a second conductivity type, a third semiconductor region of the first conductivity type, a fourth semiconductor region of the second conductivity type, and a first gate electrode. The first semiconductor region is provided on the first electrode. The second semiconductor region is provided on the first semiconductor region. The third semiconductor region is provided on the second semiconductor region. The fourth semiconductor region is provided on the third semiconductor region. The first gate electrode faces the third semiconductor region via a first gate insulating layer. The fifth semiconductor region is of the first conductivity type and provided around the main element region in a first plane. The first plane is perpendicular to a first direction from the first electrode toward the first semiconductor region. The sense element region includes the first semiconductor region, the second semiconductor region, a sixth semiconductor region of the first conductivity type, a seventh semiconductor region of the second conductivity type, and a second gate electrode. The sixth semiconductor region is provided on the second semiconductor region. The seventh semiconductor region is provided on the sixth semiconductor region. The second gate electrode faces the sixth semiconductor region via a second gate insulating layer. The sense element region is separated from the main element region. An area of the sense element region in the first plane is smaller than an area of the main element region in the first plane. The eighth semiconductor region is of the first conductivity type and provided around the sense element region in the first plane. The ninth semiconductor region is of the first conductivity type and provided between the main element region and the sense element region. The ninth semiconductor region is located on the second semiconductor region and electrically connected to the eighth semiconductor region. The second electrode is provided on the main element region and electrically connected to the third semiconductor region, the fourth semiconductor region, and the fifth semiconductor region. The third electrode is provided on the sense element region and electrically connected to the sixth semiconductor region, the seventh semiconductor region, and the eighth semiconductor region. The fourth electrode is provided on the ninth semiconductor region via an insulating layer, and electrically connected to the first gate electrode and the second gate electrode.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n, n⁻ and p⁺, p, p⁻ represent relative levels of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative levels of net impurity concentrations after the mutual compensation of these impurities when respective regions include both of a p-type impurity and an n-type impurity.

The embodiments described below may be implemented by reversing the p-type and the n-type of the semiconductor regions.

### First Embodiment

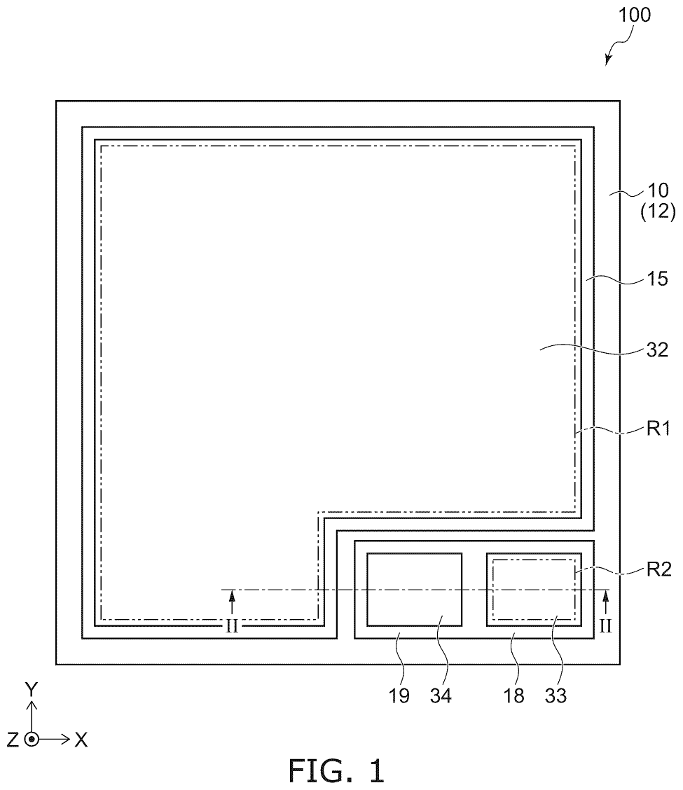

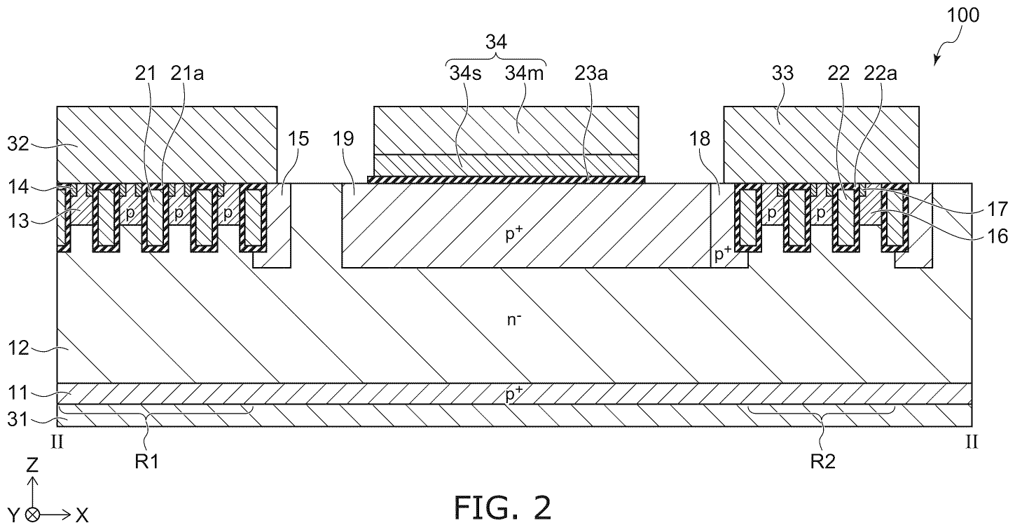

FIG. 1 is a plan view illustrating a semiconductor device according to a first embodiment. FIG. 2 is a II-II cross-sectional view of FIG. 1.

As shown in FIGS. 1 and 2, the semiconductor device according to the first embodiment includes a semiconductor layer 10, a collector electrode 31 (a first electrode), an emitter electrode 32 (a second electrode), a sense emitter electrode 33 (a third electrode), and a gate pad 34 (a fourth electrode). The semiconductor layer 10 includes a p⁺-type (a first conductivity type) collector region 11 (a first semiconductor region), an n⁻ type (a second conductivity type) base region 12 (a second semiconductor region), a p-type base region 13 (a third semiconductor region), an n⁺-type emitter region 14 (a fourth semiconductor region), a p⁺-type guard ring region 15 (a fifth semiconductor region), a p-type base region 16 (a sixth semiconductor region), an n⁺-type emitter region 17 (a seventh semiconductor region), a p⁺-type guard ring region 18 (an eighth semiconductor region), a p⁺-type semiconductor region 19 (a ninth semiconductor region), a gate electrode 21 (a first gate electrode), and a gate electrode 22 (a second gate electrode). The semiconductor device 100 is an insulated gate bipolar transistor (IGBT).

An XYZ orthogonal coordinate system is used in the description of the embodiments. A direction from the collector electrode 31 toward the p⁺-type collector region 11 is taken as a Z-direction (a first direction); and two mutually-orthogonal directions perpendicular to the Z-direction are taken as an X-direction (a second direction) and a Y-direction (a third direction). In the description, the direction from the collector electrode 31 toward the p⁺-type collector region 11 is called “up/upward/above”, and the opposite direction is called “down/downward/below”. These directions are based on the relative positional relationship between the collector electrode 31 and the p⁺-type collector region 11, and are independent of the direction of gravity.

As shown in FIG. 1, the emitter electrode 32, the sense emitter electrode 33, and the gate pad 34 are provided on the upper surface of the semiconductor device 100. The emitter electrode 32, the sense emitter electrode 33, and the gate pad 34 are separated from each other.

The semiconductor layer 10 includes a main element region R1 and a sense element region R2. In FIG. 1, the main element region R1 and the sense element region R2 are shown by a two-dot chain line. The main element region R1 and the sense element region R2 are separated from each other in a direction perpendicular to the Z-direction. The area in the X-Y plane (a first plane) of the sense element region R2 is smaller than the area in the X-Y plane of the main element region R1. The emitter electrode 32 is located on the main element region R1. The sense emitter electrode 33 is located on the sense element region R2.

As shown in FIG. 2, the collector electrode 31 is provided on the lower surface of the semiconductor device 100. The collector electrode 31 is located below the main element region R1 and the sense element region R2.

The p⁺-type collector region 11 is provided on the collector electrode 31 and is electrically connected to the collector electrode 31. The n⁻ type base region 12 is provided on the p⁺-type collector region 11. The p⁺-type collector region 11 and the n⁻ type base region 12 are provided in both the main element region R1 and the sense element region R2.

The p-type base region 13 is provided on the n⁻ type base region 12 in the main element region R1. The n⁺-type emitter region 14 is provided on the p-type base region 13. The gate electrode 21 faces the p-type base region 13 via a gate insulating layer 21a (a first gate insulating layer) in the X-direction.

The emitter electrode 32 is located on the p-type base region 13, the n⁺-type emitter region 14, and the gate electrode 21, and is electrically connected to the p-type base region 13 and the n⁺-type emitter region 14. The gate electrode 21 and the emitter electrode 32 are electrically isolated by the gate insulating layer 21a.

In the main element region R1, the p-type base region 13 and the gate electrode 21 are provided alternately in the X-direction. Each p-type base region 13 and each gate electrode 21 extend in the Y-direction. Multiple n⁺-type emitter regions 14 are respectively provided on multiple p-type base regions 13. Alternatively, the n⁺-type emitter region 14 may be omitted on a part of the p-type base regions 13. A part of the gate electrodes 21 may be electrically connected to the emitter electrode 32.

The p⁺-type guard ring region 15 is provided around the main element region R1 in the X-Y plane. The p-type impurity concentration in the p⁺-type guard ring region 15 is greater than the p-type impurity concentration in the p-type base region 13. The lower end of the p⁺-type guard ring region 15 is located below the lower end of the p-type base region 13. The lower end of the p⁺-type guard ring region 15 may be located below the lower end of the gate electrode 21.

The p-type base region 16 is provided on the n⁻ type base region 12 in the sense element region R2. The n⁺-type emitter region 17 is provided on the p-type base region 16. The gate electrode 22 faces the p-type base region 16 via a gate insulating layer 22a (a second gate insulating layer) in the X-direction.

The sense emitter electrode 33 is located on the p-type base region 16, the n⁺-type emitter region 17, and the gate electrode 22, and is electrically connected to the p-type base region 16 and the n⁺-type emitter region 17. The gate electrode 22 and the sense emitter electrode 33 are electrically isolated by the gate insulating layer 22a.

In the sense element region R2, the p-type base region 16 and the gate electrode 22 are provided alternately in the X-direction. Each p-type base region 16 and each gate electrode 22 extend in the Y-direction. Alternatively, the p-type base region 16 and the gate electrode 22 may be provided alternately in the Y-direction, and each p-type base region 16 and each gate electrode 22 may extend in the X-direction. Multiple n⁺-type emitter regions 17 are respectively provided on multiple p-type base regions 16. The n⁺-type emitter region 17 may be omitted on a part of the p-type base regions 16, and a part of the gate electrodes 22 may be electrically connected to the sense emitter electrode 33.

The p⁺-type guard ring region 18 is provided around the sense element region R2 in the X-Y plane. The p-type impurity concentration in the p⁺-type guard ring region 18 is greater than the p-type impurity concentration in the p-type base region 16. The lower end of the p⁺-type guard ring region 18 is located below the lower end of the p-type base region 16. The lower end of the p⁺-type guard ring region 18 may be located below the lower end of the gate electrode 22.

The p⁺-type semiconductor region 19 is provided between the main element region R1 and the sense element region R2. The p⁺-type semiconductor region 19 is located on the n⁻ type base region 12 and is electrically connected to the p⁺-type guard ring region 18. The p-type impurity concentration in the p⁺-type semiconductor region 19 may be the same as the p-type impurity concentration in the p⁺-type guard ring region 18. The p⁺-type semiconductor region 19 is separated from the p⁺-type guard ring region 15. A portion of the n⁻ type base region 12 is provided between the p⁺-type guard ring region 15 and the p⁺-type semiconductor region 19.

The gate pad 34 is provided via an insulating layer 23a on the p⁺-type semiconductor region 19. The gate pad 34 is electrically connected to multiple gate electrodes 21 and multiple gate electrodes 22.

As described above, the area of the sense element region R2 in the X-Y plane is smaller than the area of the main element region R1 in the X-Y plane. Therefore, the area of the sense emitter electrode 33 in the X-Y plane is smaller than the area of the emitter electrode 32 in the X-Y plane. The area of the gate pad 34 in the X-Y plane may be smaller than the area of the emitter electrode 32 in the X-Y plane. The number of gate electrodes 22 provided in the sense element region R2 is less than the number of first gate electrodes 21 provided in the main element region R1.

The operation of the semiconductor device 100 will now be described.

When a voltage not less than a threshold is applied to the gate electrodes 21 and 22, channels (inversion layers) are formed in the p-type base region 13 and the p-type base region 16. When the channels are formed in a state where a positive voltage with respect to the emitter electrode 32 and the sense emitter electrode 33 is applied to the collector electrode 31, the semiconductor device 100 is turned on. Electrons are injected from the n⁺-type emitter region 14 into the n⁻ type base region 12 through the channel, and holes are injected from the p⁺-type collector region 11 into the n⁻ type base region 12. Conductivity modulation occurs in the n⁻ type base region 12, and the resistance in the n⁻ type base region 12 decreases. Thereafter, when the voltage applied to the gate electrodes 21 and 22 becomes lower than the threshold, the channels of the p-type base region 13 and the p-type base region 16 disappear, and the semiconductor device 100 is turned off.

Except for the area, the structure of the sense element region R2 is substantially the same as the structure of the main element region R1. Therefore, when the semiconductor device 100 is in the on-state, currents proportional to the area ratio of the main element region R1 and the sense element region R2 flows through the main element region R1 and the sense element region R2, respectively. The current flowing through the sense element region R2 is smaller than the current flowing through the main element region R1. By detecting the current flowing through the sense element region R2, the current flowing through the main element region R1 can be calculated. The sense element region R2 is provided for monitoring the current flowing through the main element region R1.

The area of the sense element region R2 may be sufficiently smaller than the area of the main element region R1. For example, the area of the main element region R1 is designed to be not less than 3000 times and not more than 5000 times the area of the sense element region R2.

An example of the material of each component will now be described. The semiconductor layer 10 includes silicon, silicon carbide, gallium nitride, or gallium arsenide as a semiconductor material. When silicon is used as the semiconductor material, arsenic, phosphorus, or antimony is used as the n-type impurity. Boron is used as a p-type impurity. The gate electrode 21 and the gate electrode 22 include a semiconductor material such as polysilicon. N-type impurities or p-type impurities may be added to the polysilicon. The gate insulating layer 21a, the gate insulating layer 22a, and the insulating layer 23a include an insulating material such as silicon oxide, silicon nitride, or silicon oxynitride. The collector electrode 31, the emitter electrode 32, the sense emitter electrode 33, and the gate pad 34 include a metal material such as aluminum, titanium, or tungsten. As shown in FIG. 2, the gate pad 34 may be composed of a semiconductor portion 34s including polysilicon and a metal portion 34m including a metal material. N-type impurities or p-type impurities may be added to the polysilicon of the semiconductor portion 34s. The semiconductor material of the semiconductor portion 34s may be the same as the semiconductor material of the gate electrode 21 or the gate electrode 22.

An example of the impurity concentration in each semiconductor region will now be described.

The p-type impurity concentration in the p⁺-type collector region 11 is not less than 1.0×10¹⁵ atom/cm³ and not more than 1.0×10¹⁷ atom/cm³. The n-type impurity concentration in the n⁻ type base region 12 is not less than 5.0×10¹³ atom/cm³ and not more than 5.0×10¹⁴ atom/cm³. The p-type impurity concentration in the p-type base region 13 and the p-type base region 16 is not less than 1.0×10¹⁵ atom/cm³ and not more than 1.0×10¹⁶ atom/cm³. The n-type impurity concentration in each of the n⁺-type emitter region 14 and the n⁺-type emitter region 17 is not less than 1.0×10¹⁸ atom/cm³ and not more than 1.0×10²¹ atom/cm³. The p-type impurity concentration in each of the p⁺-type guard ring region 15, the p⁺-type guard ring region 18, and the p⁺-type semiconductor region 19 is not less than 5.0×10¹⁷ atom/cm³ and not more than 5.0×10¹⁸ atom/cm³. The p-type impurity concentration in the p⁺-type guard ring region 18 and the p-type impurity concentration in the p⁺-type semiconductor region 19 may be the same, and the p⁺-type guard ring region 18 and the p⁺-type semiconductor region 19 may be formed as a single region.

Advantages of the first embodiment will now be described.

Electrostatic discharge (ESD) may occur in the semiconductor device or in the electrical circuit to which the semiconductor device is connected. When ESD occurs, a large voltage is temporarily applied to the main element region R1 and the sense element region R2. At this time, there is a possibility that the insulating layers, such as the gate insulating layer 22a, may break down. According to the examination by the inventors of the present application, it was found that there was a correlation between the area of the element and the breakdown caused by ESD. In other words, breakdown due to ESD is more likely to occur as the area of the element is smaller. As described above, the area of the sense element region R2 is smaller than the area of the main element region R1. Therefore, in the sense element region R2, breakdown due to ESD is more likely to occur than in the main element region R1.

In the first embodiment, the p⁺-type semiconductor region 19 is provided directly below the gate pad 34. The p⁺-type semiconductor region 19 is provided for improving the breakdown voltage of the semiconductor device 100. By providing the p⁺-type semiconductor region 19, the electric field concentration in the region directly below the gate pad 34 can be suppressed, reducing the possibility of breakdown in the semiconductor device 100. The gate pad 34 faces the p⁺-type semiconductor region 19 via the insulating layer 23a, and there is an insulating film capacitance between the p⁺-type semiconductor region 19 and the gate pad 34. In the first embodiment, the p⁺-type semiconductor region 19 is electrically connected to the p⁺-type guard ring region 18. When the p⁺-type semiconductor region 19 is connected to the p⁺-type guard ring region 18, the insulating film capacitance of the insulating layer 23a is added to the insulating film capacitance of the gate insulating layer 22a. As a result, when ESD occurs, the occurrence of breakdown in the sense element region R2 can be suppressed. According to the first embodiment, the ESD withstand capability of the sense element region R2 can be increased.

### Second Embodiment

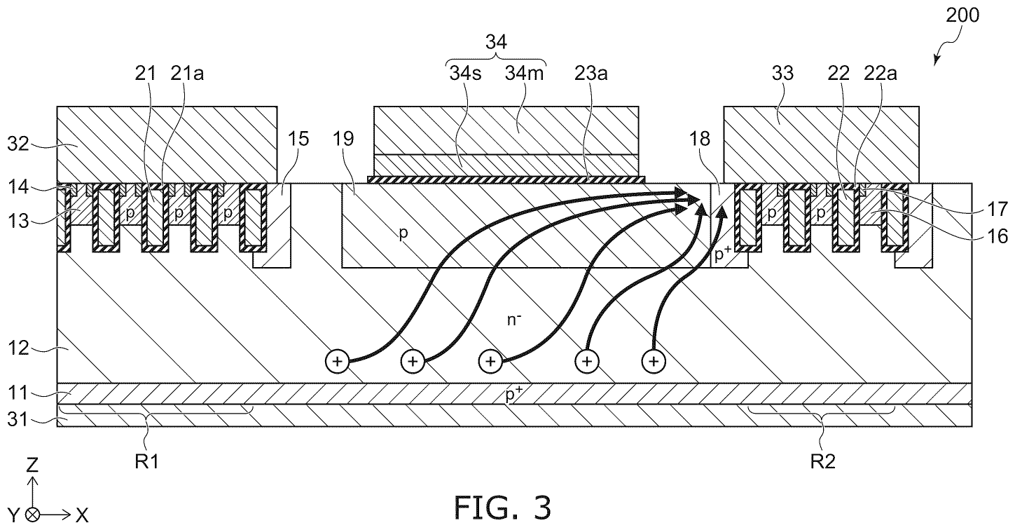

FIG. 3 is a cross-sectional view illustrating a semiconductor device according to a second embodiment.

The semiconductor device 200 according to the second embodiment shown in FIG. 3 differs in the p-type impurity concentration in the p⁺-type semiconductor region 19 compared to the semiconductor device 100 according to the first embodiment. The p-type impurity concentration in the p⁺-type semiconductor region 19 is less than the p-type impurity concentration in the p⁺-type guard ring region 18.

As shown in FIG. 3, during operation of the semiconductor device 200, holes injected into the region below the gate pad 34 flow through the p⁺-type semiconductor region 19 toward the sense emitter electrode 33. At this time, the hole current concentrates in the p⁺-type guard ring region 18, possibly causing breakdown in the sense element region R2.

According to the second embodiment, by having a lower p-type impurity concentration in the p⁺-type semiconductor region 19, the electrical resistance to holes in the p⁺-type semiconductor region 19 can be increased. Thereby, the hole current flowing in the p⁺-type guard ring region 18 can be reduced, and the occurrence of breakdown in the sense element region R2 can be suppressed.

The lower the p-type impurity concentration in the p⁺-type semiconductor region 19, the more the hole current flowing through the p⁺-type semiconductor region 19 to the p⁺-type guard ring region 18 can be reduced. On the other hand, when the p-type impurity concentration in the p⁺-type semiconductor region 19 is excessively low, the insulating film capacitance of the insulating layer 23a may not effectively contribute to the insulating film capacitance of the gate insulating layer 22a. Therefore, the p-type impurity concentration in the p⁺-type semiconductor region 19 is preferably not less than the p-type impurity concentration in the p-type base region 16.

### Third Embodiment

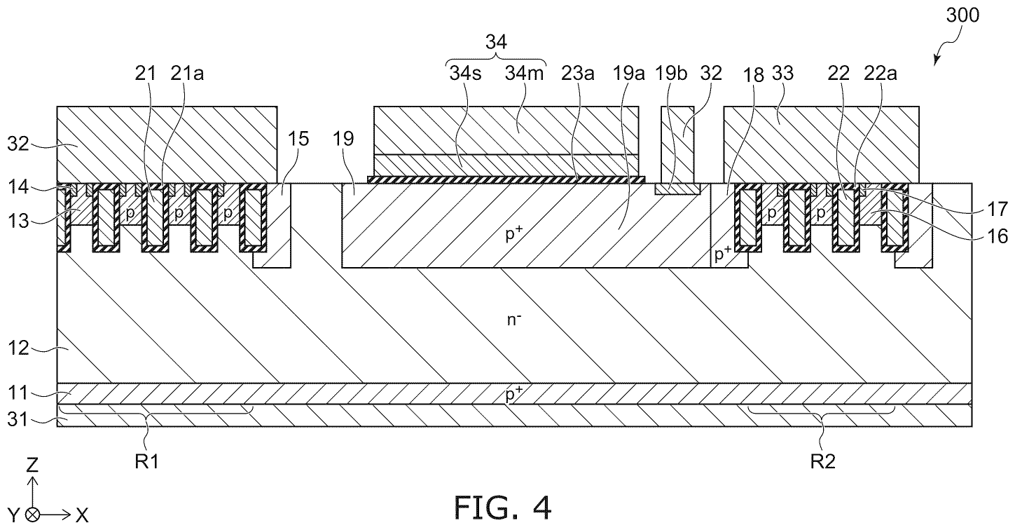

FIG. 4 is a cross-sectional view illustrating a semiconductor device according to a third embodiment.

The semiconductor device 300 according to the third embodiment shown in FIG. 4 differs in the structure of the p⁺-type semiconductor region 19 compared with the semiconductor device 100 according to the first embodiment. In the semiconductor device 300, the p⁺-type semiconductor region 19 includes a first portion 19a and a second portion 19b. The first portion 19a is located directly below the gate pad 34. The second portion 19b is located between the first portion 19a and the p⁺-type guard ring region 18 in the X-direction. The p-type impurity concentration in the second portion 19b is greater than the p-type impurity concentration in the first portion 19a. For example, the p-type impurity concentration in the second portion 19b is designed to be not less than 10 times and not more than 20 times the p-type impurity concentration in the first portion 19a. A portion of the emitter electrode 32 is provided on the second portion 19b, and the second portion 19b is electrically connected to the emitter electrode 32.

According to the third embodiment, by providing the second portion 19b having a higher p-type impurity concentration, holes flowing through the p⁺-type semiconductor region 19 can be discharged from the second portion 19b. Thereby, the hole current flowing in the p⁺-type guard ring region 18 can be reduced, suppressing the occurrence of breakdown in the sense element region R2.

### Fourth Embodiment

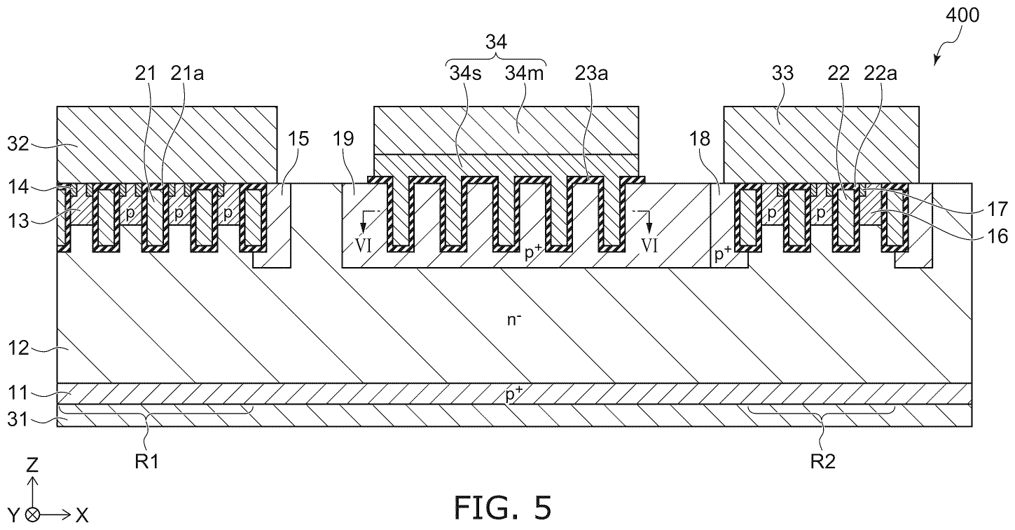

FIG. 5 is a cross-sectional view illustrating a semiconductor device according to a fourth embodiment.

The semiconductor device 400 according to the fourth embodiment shown in FIG. 5 differs in the structure of the gate pad 34 compared with the semiconductor device 100 according to the first embodiment. In the semiconductor device 400, a portion of the gate pad 34 faces the p⁺-type semiconductor region 19 in the X-direction via the insulating layer 23a.

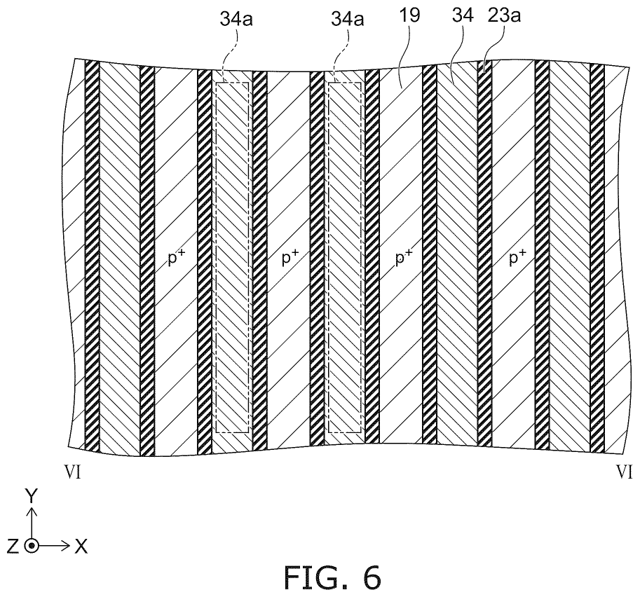

FIG. 6 is a cross-sectional view illustrating an example of a VI-VI cross-section of FIG. 5.

As shown in FIG. 6, the gate pad 34 includes a first extending portion 34a that extends in the Y-direction. Multiple first extending portions 34a are provided in the X-direction. The multiple first extending portions 34a are separated from each other. Each first extending portion 34a faces the p⁺-type semiconductor region 19 in the X-direction via the insulating layer 23a.

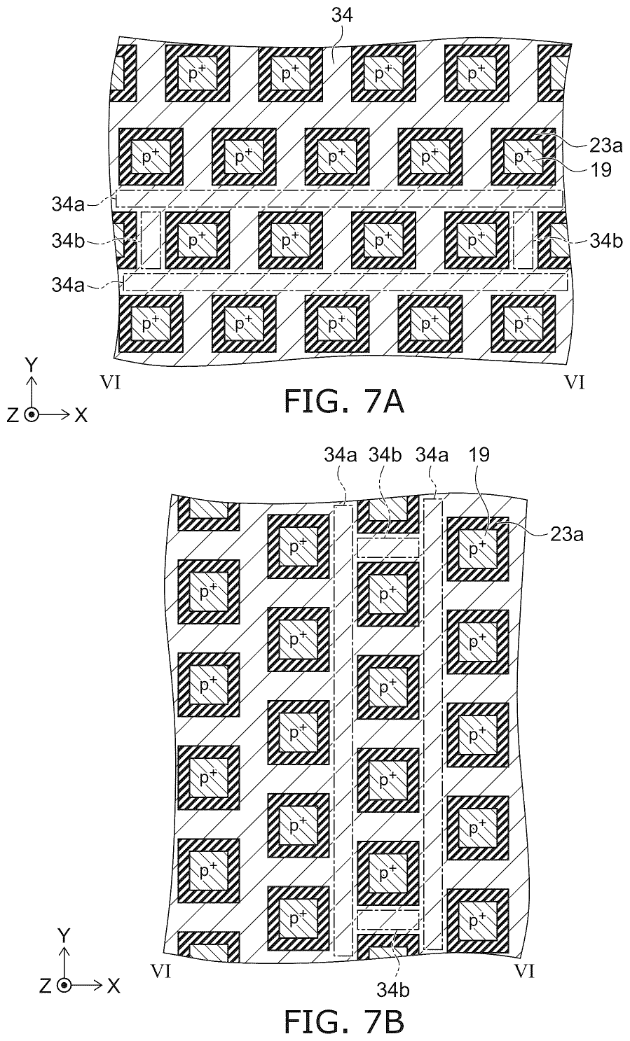

FIGS. 7A and 7B are cross-sectional views illustrating other examples of the VI-VI cross-section.

As shown in FIG. 7A, the gate pad 34 may include a first extending portion 34a that extends in the X-direction and a second extending portion 34b that extends in the Y-direction. Multiple first extending portions 34a are separated from each other in the Y-direction. Between adjacent first extending portions 34a in the Y-direction, multiple second extending portions 34b are provided. The multiple first extending portions 34a and the multiple second extending portions 34b are arranged in a grid pattern, and the p⁺-type semiconductor regions 19 are arranged in a staggered pattern between these extending portions.

In the example shown in FIG. 7B, the first extending portion 34a extends in the Y-direction, and the second extending portion 34b extends in the X-direction. Multiple first extending portions 34a are separated from each other in the X-direction. Between adjacent first extending portions 34a in the X-direction, multiple second extending portions 34b are provided. As shown in FIGS. 7A and 7B, as long as the first extending portion 34a and the second extending portion 34b extend in mutually orthogonal directions, the arrangement of the first extending portion 34a and the second extending portion 34b can be changed as needed.

According to the fourth embodiment, the facing area between the gate pad 34 and the p⁺-type semiconductor region 19 can be increased compared to the first embodiment. In particular, according to the structure shown in FIG. 7A or 7B, the facing area between the gate pad 34 and the p⁺-type semiconductor region 19 can be further increased. The insulating film capacitance of the insulating layer 23a increases, and the occurrence of breakdown due to ESD in the sense element region R2 can be further suppressed.

Fifth Embodiment

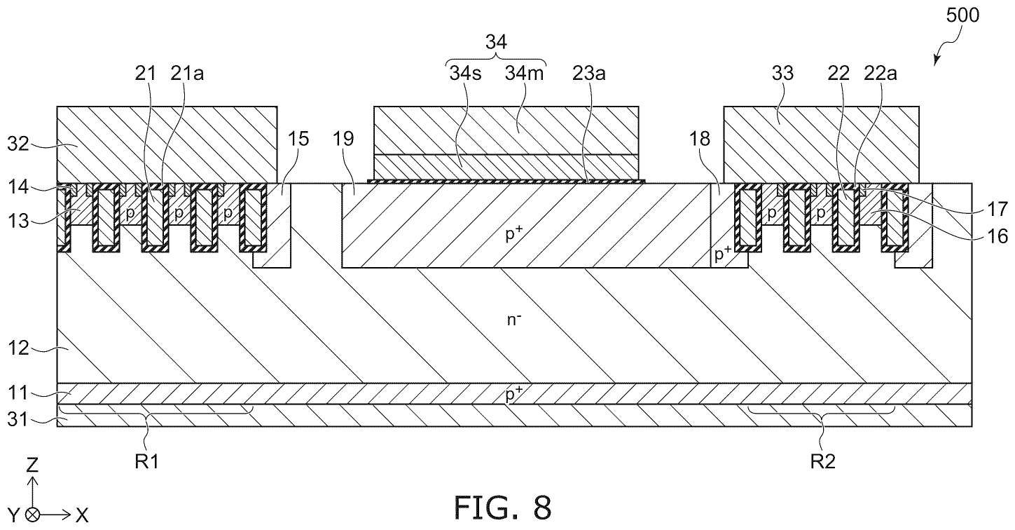

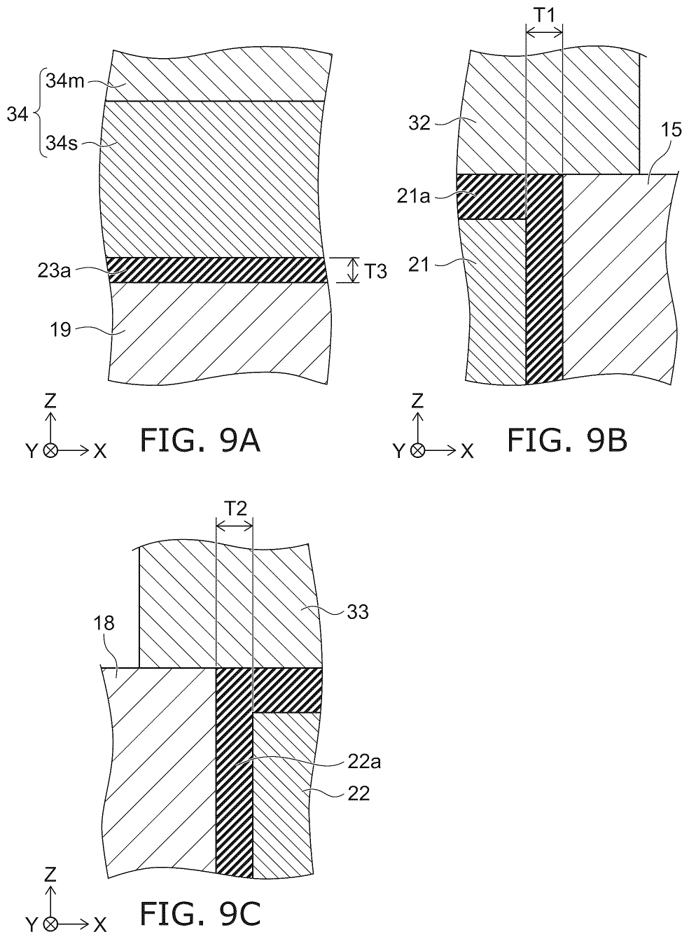

FIG. 8 is a cross-sectional view illustrating a semiconductor device according to a fifth embodiment. FIGS. 9A to 9C are enlarged cross-sectional views of portions of FIG. 8.

The semiconductor device 500 according to the fifth embodiment shown in FIG. 8 differs in the thickness of the insulating layer 23a compared with the semiconductor device 100 according to the first embodiment. In the semiconductor device 500, the thickness of the insulating layer 23a is smaller than the thickness of the gate insulating layer 21a and the thickness of the gate insulating layer 22a.

FIG. 9A is an enlarged cross-sectional view of the vicinity of the insulating layer 23a. FIG. 9B is an enlarged cross-sectional view of the vicinity of the gate insulating layer 21a. FIG. 9C is an enlarged cross-sectional view of the vicinity of the gate insulating layer 22a. As shown in FIG. 9A, the thickness T3 of the insulating layer 23a is represented by the distance in the Z-direction between the p⁺-type semiconductor region 19 and the gate pad 34. As shown in FIG. 9B, the thickness T1 of the gate insulating layer 21a is represented by the distance in the X-direction between the p⁺-type guard ring region 15 and the gate electrode 21. As shown in FIG. 9C, the thickness T2 of the gate insulating layer 22a is represented by the distance in the X-direction between the p⁺-type guard ring region 18 and the gate electrode 22. In the fifth embodiment, the thickness T3 is smaller than the thickness T1 and smaller than the thickness T2.

According to the fifth embodiment, the insulating film capacitance between the p⁺-type semiconductor region 19 and the gate pad 34 can be increased by reducing the thickness T3. By increasing the insulating film capacitance, the occurrence of breakdown due to ESD in the sense element region R2 can be further suppressed.

Instead of reducing the thickness T3, the relative dielectric constant of the insulating material of the insulating layer 23a may be greater than the relative dielectric constant of the insulating material of the gate insulating layer 21a or the gate insulating layer 22a. By using an insulating material having a larger dielectric constant for the insulating layer 23a, the insulating film capacitance between the p⁺-type semiconductor region 19 and the gate pad 34 can be increased. Alternatively, in addition to reducing the thickness T3, an insulating material having a larger dielectric constant may be used for the insulating layer 23a.

Each of the embodiments described above can be combined as needed. For example, the second or third embodiment may be combined with the fourth or fifth embodiment to increase the insulating film capacitance. The structures of the second to fifth embodiments may be combined.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a first electrode;
a main element region including
a first semiconductor region of a first conductivity type provided on the first electrode,
a second semiconductor region of a second conductivity type provided on the first semiconductor region,
a third semiconductor region of the first conductivity type provided on the second semiconductor region,
a fourth semiconductor region of the second conductivity type provided on the third semiconductor region, and
a first gate electrode facing the third semiconductor region via a first gate insulating layer;
a fifth semiconductor region of the first conductivity type provided around the main element region in a first plane that is perpendicular to a first direction from the first electrode toward the first semiconductor region;
a sense element region including
the first semiconductor region,
the second semiconductor region,
a sixth semiconductor region of the first conductivity type provided on the second semiconductor region,
a seventh semiconductor region of the second conductivity type provided on the sixth semiconductor region, and
a second gate electrode facing the sixth semiconductor region via a second gate insulating layer,
the sense element region being separated from the main element region, and an area of the sense element region in the first plane being smaller than an area of the main element region in the first plane;
an eighth semiconductor region of the first conductivity type provided around the sense element region in the first plane;
a ninth semiconductor region of the first conductivity type provided between the main element region and the sense element region, the ninth semiconductor region located on the second semiconductor region and electrically connected to the eighth semiconductor region;
a second electrode provided on the main element region and electrically connected to the third semiconductor region, the fourth semiconductor region, and the fifth semiconductor region;
a third electrode provided on the sense element region and electrically connected to the sixth semiconductor region, the seventh semiconductor region, and the eighth semiconductor region; and
a fourth electrode provided on the ninth semiconductor region via an insulating layer, and electrically connected to the first gate electrode and the second gate electrode.

2. The semiconductor device according to claim 1, wherein
an impurity concentration of the first conductivity type in the ninth semiconductor region is less than an impurity concentration of the first conductivity type in the eighth semiconductor region.

3. The semiconductor device according to claim 2, wherein
the impurity concentration of the first conductivity type in the ninth semiconductor region is not less than an impurity concentration of the first conductivity type in the sixth semiconductor region.

4. The semiconductor device according to claim 1, wherein
the ninth semiconductor region includes:
a first portion located directly below the fourth electrode; and
a second portion located between the first portion and the eighth semiconductor region in a direction perpendicular to the first direction,
an impurity concentration of the first conductivity type in the second portion is greater than an impurity concentration of the first conductivity type in the first portion.

5. The semiconductor device according to claim 4, wherein
the second portion is electrically connected to the third electrode.

6. The semiconductor device according to claim 1, wherein
a portion of the fourth electrode faces the ninth semiconductor region via the insulating layer in a direction perpendicular to the first direction.

7. The semiconductor device according to claim 6, wherein
the portion of the fourth electrode includes:
a first extending portion that extends in a second direction perpendicular to the first direction; and
a second extending portion that extends in a third direction perpendicular to the first direction and the second direction,
the first extending portion is provided in plurality in the third direction, and
the second extending portion is provided in plurality in the second direction between two of a plurality of the first extending portions adjacent in the third direction.

8. The semiconductor device according to claim 1, wherein
a thickness of the insulating layer is smaller than a thickness of the second gate insulating layer.

9. The semiconductor device according to claim 1, wherein
a relative permittivity of an insulating material included in the insulating layer is greater than a relative permittivity of an insulating material included in the second gate insulating layer.

10. The semiconductor device according to claim 1, wherein
an area of the third electrode in the first plane is smaller than an area of the second electrode in the first plane.

11. The semiconductor device according to claim 10, wherein
an area of the fourth electrode in the first plane is smaller than an area of the second electrode in the first plane.

12. The semiconductor device according to claim 1, wherein
an area of the main element region in the first plane is not less than 3000 times and not more than 5000 times an area of the sense element region in the first plane.

13. The semiconductor device according to claim 1, wherein
a plurality of the first gate electrodes separated from each other is provided,
a plurality of the second gate electrodes separated from each other is provided, and
the fourth electrode is electrically connected to the plurality of first gate electrodes and the plurality of second gate electrodes.

14. The semiconductor device according to claim 13, wherein
a number of the plurality of second gate electrodes provided in the sense element region is less than a number of the plurality of first gate electrodes provided in the main element region.

15. The semiconductor device according to claim 1, wherein
the fourth electrode includes:
a semiconductor portion including a semiconductor material; and
a metal portion provided on the semiconductor portion and including a metal material.

16. The semiconductor device according to claim 15, wherein
the semiconductor material included in the semiconductor portion is the same as a semiconductor material included in the first gate electrode and a semiconductor material included in the second gate electrode.

17. The semiconductor device according to claim 1, wherein
a lower end of the fifth semiconductor region is located below a lower end of the third semiconductor region.

18. The semiconductor device according to claim 17, wherein
the lower end of the fifth semiconductor region is located below a lower end of the first gate electrode.

19. The semiconductor device according to claim 1, wherein
a lower end of the eighth semiconductor region is located below a lower end of the sixth semiconductor region.

20. The semiconductor device according to claim 19, wherein
the lower end of the eighth semiconductor region is located below a lower end of the second gate electrode.
